(19) United States
(12) Patent Application Publication
(10) Pub. No.: US 2025/0069890 A1
(43) Pub. Date: Feb. 27, 2025

(54) METHOD FOR PERFORMING NANOTRANSFER WITHOUT CHEMICAL TREATMENT AND SUBSTRATE FABRICATED BY THE METHOD

(71) Applicants: KOREA INSTITUTE OF MACHINERY & MATERIALS, Daejeon (KR); NANYANG TECHNOLOGICAL UNIVERSITY, Singapore (SG)

(72) Inventors: Jun-ho JEONG, Daejeon (KR); Zhijun ZHAO, Busan (KR); Soon-Hyoung HWANG, Daejeon (KR); Sohee JEON, Seoul (KR); Munho KIM, Singapore (SG); Sang Ho SHIN, Singapore (SG)

(73) Assignee: KOREA INSTITUTE OF MACHINERY & MATERIALS, Daejeon (KR)

(21) Appl. No.: 18/721,939

(22) PCT Filed: Dec. 22, 2022
(86) PCT No.: PCT/KR2022/021119

§ 371 Date: Jun. 20, 2024

(30) Foreign Application Priority Data
Dec. 23, 2021 (KR) 10-2021-0186617

(51) Int. Cl. H01L 21/306

(52) U.S. Cl. CPC H01L 21/30604

(57) ABSTRACT

In a method for performing nanotransfer without chemical treatment and a substrate fabricated by the method, the method includes, (a) forming a polymer mold having a mold protrusion, the mold protrusion being formed on a lower surface of the polymer mold and having a predetermined pattern, (b) depositing a metal on the lower surface of the polymer mold, to form a metal layer on the mold protrusion, (c) positioning the polymer mold on an upper surface of a substrate body at a predetermined temperature and pressurizing the substrate body by a predetermined time with a predetermined pressure, so that the metal layer is transferred on the upper surface of the substrate body according to a predetermined pattern, and (d) detaching the polymer mold from the substrate body, so that the polymer mold is separated from the metal layer transferred on the upper surface of the substrate body.

### BACKGROUND

### 1. Field of Disclosure

The present disclosure of invention relates to a method for performing nanotransfer without chemical treatment and a substrate fabricated by the method, and more specifically the present disclosure of invention relates to a method for performing nanotransfer without chemical treatment and a substrate fabricated by the method, for forming a metal pattern on the substrate simply and inexpensively without chemical treatment.

### 2. Description of Related Technology

In general, various lithographic techniques, such as nanosphere lithography, photo lithography, interference lithography and e-beam lithography, has been widely used to form desirable metal catalysts on the top surface of a semiconductor substrate for metal-assisted chemical etching (MacEtch). These lithographic methods have disadvantages such as expensive costs, time-consuming processes, a defect-free area patterned in a limited size, and complex processes having a patterning limiting adoption of metal-assisted chemical etching, a metal deposition and a lift-off process. Therefore, in order to advance nanostructure science and technology, it is important to overcome the above disadvantages.

Recently, new lithographic methods, such as a metal-assisted chemical etching based on colloidal lithography and tip-based lithography, have enabled the processing of silicon (Si) nanowire (NW) arrays with precisely controlled diameters dependent on the quality (i.e. uniformity and continuity) of the patterned metal catalyst. However, it is difficult to obtain high-quality metal nanopatterns at wafer-scale using the colloidal lithography due to defects during the metal patterning process, such as formation of grain boundaries and missing spheres. In addition, the tip-based lithography suffers from low patterning efficiency and limited pattern area (with a maximum area of 1 cm²). Thus, new lithographic methods are needed that can realize the further formation of high-quality metal nanopatterns and silicon nanostructure arrays with good uniformity and controllability at the wafer-scale.

### SUMMARY

The present invention is developed to solve the above-mentioned problems of the related arts. The present invention provides a method for performing nanotransfer and a substrate fabricated by the method, capable of firmly transferring a metal pattern to the substrate without chemical treatments such as chemical surface treatment, chemical adhesive layers, chemical solvents and so on.

In addition, the present invention also provides a method for performing nanotransfer and a substrate fabricated by the method, capable of transferring the metal pattern to the substrate simply and at low cost without defects.

In addition, the present invention also provides a method for performing nanotransfer and a substrate fabricated by the method, capable of easily forming nanostructures according to the metal pattern transferred on the substrate.

In addition, the present invention also provides a method for performing nanotransfer and a substrate fabricated by the method, capable of forming the nanostructures on the substrate over a relatively larger area.

According to an example embodiment, the method includes, (a) forming a polymer mold having a mold protrusion, the mold protrusion being formed on a lower surface of the polymer mold and having a predetermined pattern, (b) depositing a metal on the lower surface of the polymer mold, to form a metal layer on the mold protrusion, (c) positioning the polymer mold on an upper surface of a substrate body at a predetermined temperature and pressurizing the substrate body by a predetermined time with a predetermined pressure, so that the metal layer is transferred on the upper surface of the substrate body according to a predetermined pattern, and (d) detaching the polymer mold from the substrate body, so that the polymer mold is separated from the metal layer transferred on the upper surface of the substrate body.

In an example, the predetermined temperature may be between about 160° C. and about 200° C., the predetermined pressure may be between about 3 bar and about 6 bar, and the predetermined time may be between about 1 minutes and about 10 minutes.

In an example, the metal layer may have a thickness between about 20 nm and about 40 nm.

In an example, the substrate body may include at least one of silicon, germanium and gallium arsenide, and the metal may include one of gold, silver and platinum.

In an example, in the step (d), the polymer mold may be cooled down for about 0.9 minutes to 1.1 minutes with a temperature of about 23° C. to 28° C., and then the polymer mold may be separated from the substrate body.

In an example, the method may further include coating an etching solution on the upper surface of the substrate body, so that an area in which the metal layer remains may be removed and nanostructures are generated, after the step (d).

In an example, the etching solution may include acids having hydrofluoric acid or sulfuric acid, oxidizing agents having hydrogen peroxide or potassium permanganate, isopropyl alcohol and deionized water.

In an example, in the step (c), the upper surface of the substrate body may not be chemically treated.

According to another example embodiment, the substrate includes a substrate body having at least one of silicon, germanium and gallium arsenide, and a metal layer transferred on an upper surface of the substrate body with a predetermined pattern. Native oxide is generated between the substrate body and the metal layer, a eutectic bonding force acts between the metal layer and the native oxide, so that the substrate body and the metal layer are physically combined with each other.

In an example, the metal layer may have one of gold, silver and platinum.

In an example, the metal layer may have a thickness between about 20 nm and 40 nm.

In an example, atoms on a lower surface of the metal layer may be inserted between atoms on the upper surface of the substrate body, so that the metal layer may be physically combined with the upper surface of the substrate body and the metal layer may be transferred on the upper surface of the substrate body. In an example, the substrate may be fabricated by the method above.

According to the present example embodiments, the following effects may be obtained.

The metal pattern may be firmly transferred on the substrate without the chemical treatment such as the chemical surface treatment, the chemical adhesive, the chemical solvent and so on.

In addition, the metal pattern may be transferred on the substrate simply and at a low cost without defects.

In addition, the nanostructure may be easily formed according to the metal pattern transferred on the substrate.

In addition, the nanostructure may be formed on the substrate over a relatively larger area.

### BRIEF DESCRIPTION OF THE DRAWINGS

FIG. 1 is a flow chart showing a method for performing nanotransfer according to an example embodiment of the present invention;

FIG. 2A to FIG. 2F are process views illustrating the method for performing nanotransfer of FIG. 1;

FIG. 3A to FIG. 3C are SEM images showing a metal layer transferred to a substrate body with a pattern form using the method of FIG. 1;

FIG. 4 are images showing a transfer state of the metal layer according to a temperature of a polymer mold and a thickness of a metal; and

FIG. 5 are SEM images showing nanostructures formed on an upper surface of the substrate body using the method of FIG. 1.

* Reference numerals

| | |
|---|---|
| 10: substrate body | 11: nanostructure |
| 20: metal layer | 30: polymer mold |
| 31: mold protrusion | |

### DETAILED DESCRIPTION

The invention is described more fully hereinafter with Reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention. Spatially relative terms, such as “beneath,” “below,” “lower,” “above,” “upper” and the like, may be used herein for ease of description to describe one element or feature's relationship to another element(s) or feature(s) as illustrated in the figures.

It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the invention is described more fully hereinafter with reference to the accompanying drawings, in which embodiments of the invention are shown.

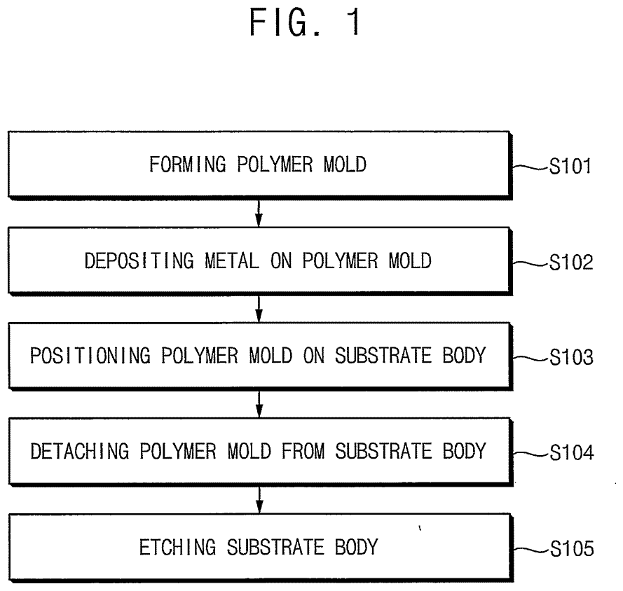

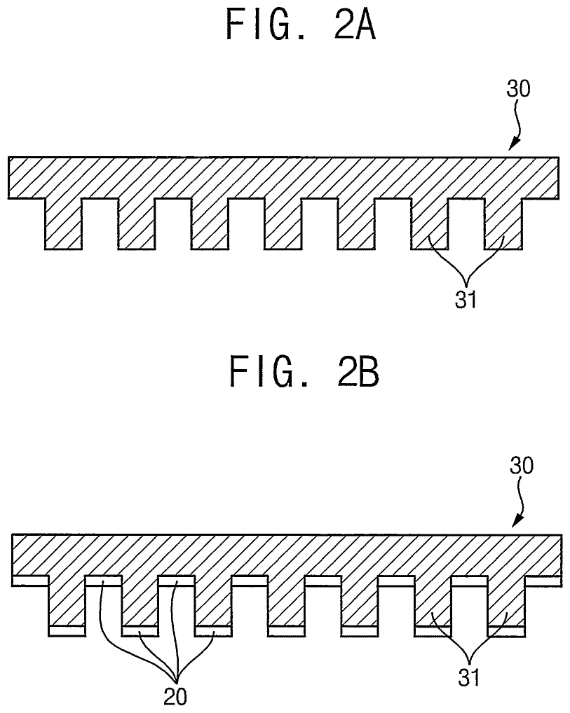

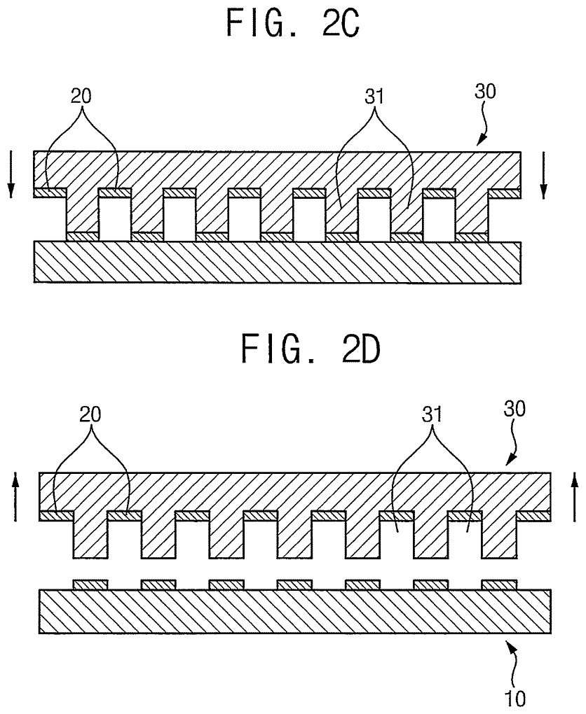

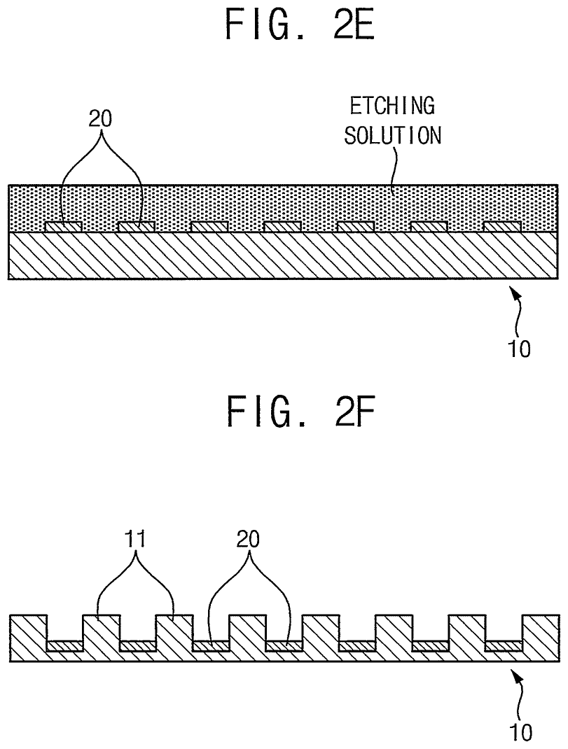

FIG. 1 is a flow chart showing a method for performing nanotransfer according to an example embodiment of the present invention. FIG. 2A to FIG. 2F are process views illustrating the method for performing nanotransfer of FIG. 1.

Referring to FIG. 1, and FIG. 2A to FIG. 2F, in the method for performing nanotransfer according to the present example embodiment, a metal layer 20 having a thin film shape is transferred on a substrate body 10 with a predetermined pattern, and the transferred metal layer 20 is used for a catalyst for forming a nanostructure on the substrate body 10.

The substrate body 10 has a predetermined thickness, and may include at least one of silicon (Si), germanium (Ge) and gallium arsenide (GaAs). Here, the substrate body 10 may have a circular plate shape with a diameter of 2 inches, 4 inches, 6 inches, 8 inches, 12 inches and so on.

The metal layer 20 may include one of gold (Au), silver (Ag) and platinum (Pt). The metal layer 20 may be formed with various kinds of patterns, such as a pattern in which multiple lines are spaced evenly and parallelly (line pattern), a pattern in which multiple holes (e.g., circular holes, cross holes, rectangular holes, etc.) are spaced evenly apart (mesh pattern), a pattern of multiple dots (e.g., circular dots, rectangular dots, cross dots, etc.) spaced evenly apart, and so on.

In the method, firstly, a polymer mold 30 is fabricated (step S101). In the step S101, the polymer mold 30 may be fabricated with a plate shape having a polymer material. In addition, a mold protrusion 31 is protruded from a lower surface of the polymer mold 30, and the mold protrusion 31 may be positioned to correspond to a pattern of the metal layer 20 to be transferred to the substrate body 10 and may each have the same height (referring to FIG. 2A). The mold protrusion 31 may include the same material as the polymer mold 30.

As illustrated in the figure, a plurality of the mold protrusions 31 is protruded downwardly with a constant distance, and the distance between the mold protrusions adjacent to each other may be variously changed.

Then, in the method, a metal is deposited on a lower surface of the polymer mold 30 (step S102). In the step S102, the metal may be deposited on a lower surface of the mold protrusion 31 and a lower surface of the polymer mold 30 between the mold protrusions 31 adjacent to each other. Due to the mold protrusion 31, the metal layer 20 may have a stepped portion in the polymer mold 30. Here, the metal layer 20 may have a predetermined pattern to correspond to the mold protrusion 31 (referring to FIG. 2B). In addition, the metal layer 20 may be deposited to be a thin film shape having a thickness between about 20 nm and about 40 nm.

A height of the mold protrusion 31 may be larger than a thickness of the metal layer 20 directly deposited on the lower surface of the polymer mold 30. The metal layer 20 deposited on the lower surface of the polymer mold 30 between the mold protrusions 31 adjacent to each other are spaced apart from the metal layer 20 deposited on the mold protrusion 31. The metal layer 20 may not be deposited on a side surface of the mold protrusion 31.

Then, in the method, the polymer mold 30 is positioned on the upper surface of the substrate body 10, and the metal layer 20 is transferred on the upper surface of the substrate body with a predetermined pattern (step S103). In the step S103, any chemical treatment, any chemical adhesion and any chemical solution are not performed on the upper surface of the substrate body 10, and the metal layer 20 deposited on the mold protrusion 31 of the polymer mold 30 makes direct contact with the upper surface of the body substrate 10 (referring to FIG. 2C).

In addition, the polymer mold 30 may be heated to have a temperature between about 160° C. and about 200° C., and may pressurize the upper surface of the substrate body 10 with a pressure between about 3 bar and about 6 bar during about 1 minutes to about 10 minutes. Thus, the metal layer 20 is physically combined with the substrate body 10, and the then the metal layer 20 may be transferred on the substrate body 10 with the predetermined pattern to correspond to the mold protrusion 31 of the polymer mold 30.

When the polymer mold 30 pressurizes the upper surface of the substrate body 10 during less than about 1 min, the metal layer 20 may not be firmly transferred to the substrate body 10. In addition, when the polymer mold 30 pressurizes the upper surface of the substrate body 10 during more than about 10 min, the metal layer 20 may be deformed and may not be uniformly transferred to the substrate body 10.

In addition, when the polymer mold 30 pressurizes the upper surface of the substrate body 10 with less than about 3 bar, the metal layer 20 may not be firmly transferred to the substrate body 10. In addition, when the polymer mold 30 pressurizes the upper surface of the substrate body 10 with more than about 6 bar, the metal layer 20 may be deformed and may not be uniformly transferred to the substrate body 10.

Here, the below physical combination may be performed between the metal layer 20 and the substrate body 10.

In the step S103, atoms of the lower surface of the metal layer 20 may be inserted between atoms of the upper surface of the substrate body 10, and thus the metal layer 20 may be physically combined with the substrate body 10 and transferred.

In addition, native oxide may be generated between the upper surface of the metal layer 20 and the lower surface of the substrate body 10, and a eutectic bonding force may act between the metal layer 20 and the native oxide, so that the metal layer 20 may be physically combined with the substrate body 10 and transferred.

In addition, a physical absorption force may act between the polymer mold 30 and the metal layer 20. The physical absorption force may be less than the eutectic bonding force acting between the metal layer 20 and the substrate body 10.

Then, in the method, the polymer mold 30 is detached from the substrate body 10 (step S104). In the step S104, since the physical absorption force between the polymer mold 30 and the metal layer 20 is less than the eutectic bonding force between the metal layer 20 and the substrate body 10, the polymer mold 30 may be easily detached from the metal layer 20, and the metal layer 20 may be physically combined with the substrate body 10 and maintained in the transferred state. Here, the metal layer 20 may be positioned on the upper surface of the substrate body 10 with a pattern (referring to FIG. 2D).

In the step S104, the polymer mold 30 may be cooled down for about 0.9 minutes to about 1.1 minutes with a temperature of about 23° C. to about 28° C., and then the polymer mold 30 may be easily separated from the metal layer 20.

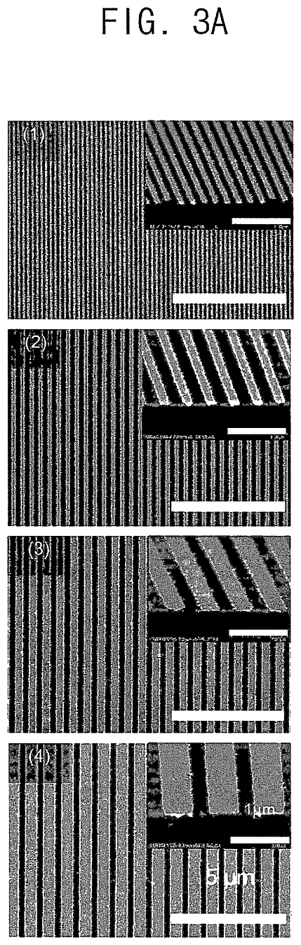

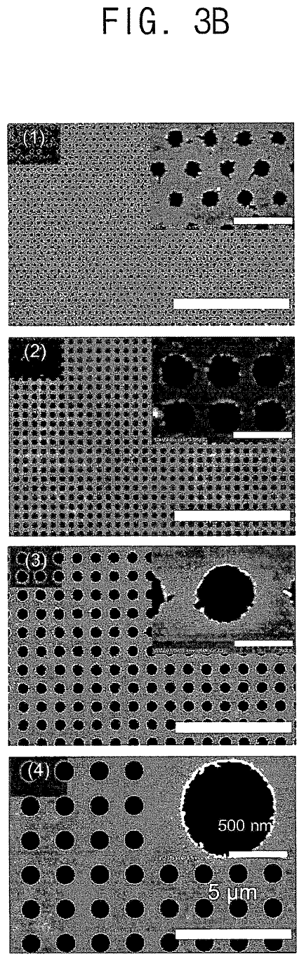

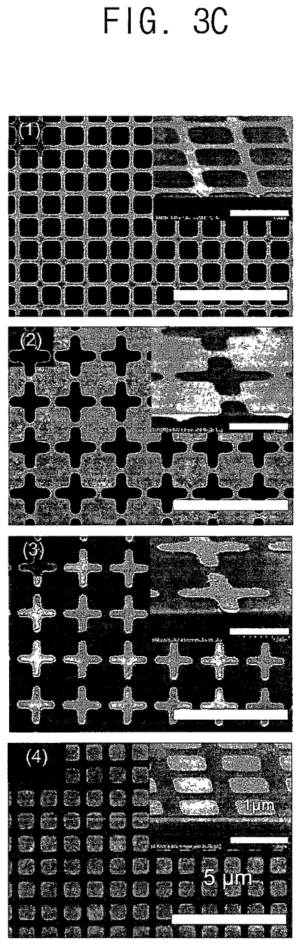

FIG. 3A to FIG. 3C are SEM images showing a metal layer transferred to a substrate body with a pattern form using the method of FIG. 1.

Referring to FIG. 3A to FIG. 3C, the metal layer 20 may be transferred to the substrate body 10. In FIG. 3A to FIG. 3C, the metal layer 20 may include a metal, and may be transferred with various kinds of patterns such as a line pattern, a mesh pattern and a dot pattern.

In FIG. 3A, the pattern includes lines each having a width of 100 nm and a space of 100 nm (referring to FIG. 3A (1)), the pattern includes lines each having a width of 200 nm and a space of 200 nm (referring to FIG. 3A (2)), the pattern includes lines each having a width of 400 nm and a space of 200 nm (referring to FIG. 3A (3)), and the pattern includes lines each having a width of 600 nm and a space of 200 nm (referring to FIG. 3A (4)).

In FIG. 3B and FIG. 3C, the pattern includes circular holes each having a diameter of 100 nm and a pitch of 300 nm (referring to FIG. 3B (1)), the pattern includes circular holes each having a diameter of 200 nm and a pitch of 400 nm (referring to FIG. 3B (2)), the pattern includes circular holes each having a diameter of 400 nm and a pitch of 800 nm (referring to FIG. 3B (3)), the pattern includes circular holes each having a diameter of 750 nm and a pitch of 1,500 nm (referring to FIG. 3B (4)), the pattern includes rectangular holes each having a width of 800 nm, having a length of 800 nm and a pitch of 1,000 nm (referring to FIG. 3C (1)), and the pattern includes cross holes each having a width of 1.4 μm and a length of 1.8 μm (referring to FIG. 3C (2)). In addition, in FIG. 3C, the pattern includes cross dots each having a width of 1.4 μm and a length of 1.8 μm (referring to FIG. 3C (3)), the pattern includes rectangular dots each having a width of 800 nm, a length of 800 nm and a pitch of 1,000 nm (referring to FIG. 3C (4)).

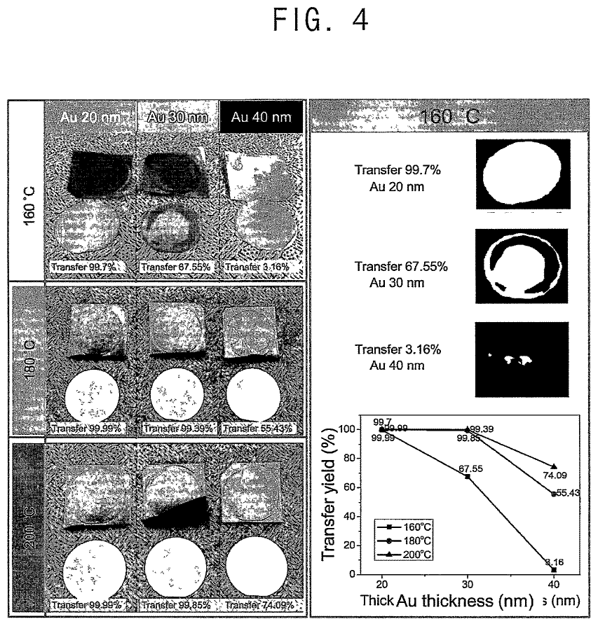

FIG. 4 are images showing a transfer state of the metal layer according to a temperature of a polymer mold and a thickness of a metal.

Referring to FIG. 4, with depositing the metal layer 20 with different temperatures and different thicknesses on the polymer mold 30, the upper surface of the substrate body 10 is pressurized with 3 bar during 5 min, and then the metal layer 20 is transferred on the upper surface of the substrate body 10 with the predetermined pattern. Here, the substrate body 10 includes silicon and the metal layer 20 includes gold.

At a temperature of 160° C., the polymer mold 30 transferred 99.7% of the metal layer 20 deposited with a thickness of 20 nm to the substrate body 10, the polymer mold 30 transferred 67.55% of the metal layer 20 deposited with a thickness of 30 nm to the substrate body 10, and the polymer mold 30 transferred 3.16% of the metal layer 20 deposited with a thickness of 40 nm to the substrate body 10. In addition, at a temperature of 180° C., the polymer mold 30 transferred 99.99% of the metal layer 20 deposited with a thickness of 20 nm to the substrate body 10, the polymer mold 30 transferred 99.39% of the metal layer 20 deposited with a thickness of 30 nm to the substrate body 10, and the polymer mold 30 transferred 55.43% of the metal layer 20 deposited with a thickness of 40 nm to the substrate body 10. In addition, at a temperature of 200° C., the polymer mold 30 transferred 99.99% of the metal layer 20 deposited with a thickness of 20 nm to the substrate body 10, the polymer mold 30 transferred 99.85% of the metal layer 20 deposited with a thickness of 30 nm to the substrate body 10, and the polymer mold 30 transferred 74.09% of the metal layer 20 deposited with a thickness of 40 nm to the substrate body 10.

When the metal layer 20 is deposited on the polymer mold 30 with the thickness of 20 nm, it may be confirmed that the metal layer 20 is entirely transferred to the substrate body 10 using the polymer mold 30 having the temperature of 160° C. to 200° C. In addition, in cases that the polymer mold 30 is deposited at the temperature of 180° C. to 200° C. with the thickness of 20 nm, with the thickness of 30 nm and with the thickness of 40 nm, the metal layer 20 may be transferred on the substrate body 10 as a whole.

Thus, the metal layer 20 may be preferably deposited on the polymer mold 30 with the thickness of 20 nm, and the polymer mold 30 may stably transfer the metal layer 20 deposited with the thickness between 20 nm and 40 nm at the temperature of 200° C. on the substrate body 10 with the predetermined pattern.

When the substrate body 10 on which the metal layer 20 is transferred is sonicated for 30 to 120 minutes while immersed in an acetone solution, the metal layer 20 may be maintained in a state transferred to the substrate body 10 without damage. Thus, the metal layer 20 may be firmly transferred to the substrate body 10 in the present example embodiment.

In the method for performing the nanotransfer according to the present example embodiment, the conditions such as the pressure, the temperature, the time and so on are controlled in transferring the metal layer 20 to the substrate body 10 with the predetermined pattern, so that the metal layer 20 may be firmly transferred to the substrate body 10. Thus, in the method for performing the nanotransfer according to the present example embodiment, without any chemical treatment such as chemical surface treatment, chemical adhesive layer, chemical solution and so on, the metal layer 20 may be physically combined with the substrate body 10 and transferred.

In addition, in the method for performing the nanotransfer according to the present example embodiment, the metal layer 20 may be transferred to the substrate body 10 via a simple and low-cost process in which the conditions such as the pressure, the temperature, the time and so on are controlled, and defects in the metal layer 20 transferred with the pattern may also be prevented.

Further, in the method, an etching solution is applied to the substrate body 10 (step S105).

The step S105 is performed after the step S104, and thus the metal layer 20 is already transferred to the substrate body 10. Here, the etching solution may include acids having hydrofluoric acid (HF) or sulfuric acid (H₂SO₄), oxidizing agents having hydrogen peroxide (H₂O₂) or potassium permanganate (KMnO₂), isopropyl alcohol and deionized water.

The substrate body 10 is immersed in the etching solution, the etching solution may be applied to the substrate body 10 (referring to FIG. 2E). The metal layer 20 transferred with the pattern acts as a catalyst for the etching solution, and thus a portion at which the metal layer 20 is formed in the substrate body may be removed.

Thus, via the step S105, the nanostructures 11 may be formed on the substrate body 10, and the nanostructures 11 may be formed between the metal layers 20 adjacent to each other (referring to FIG. 2F).

As explained above, since the metal layer 20 is physically and firmly transferred to the substrate body 10, the metal layer 20 is not detached from the substrate body 10 by the etching solution, and the metal layer 20 stably acts as the catalyst for the etching solution and is used for forming the nanostructures 11.

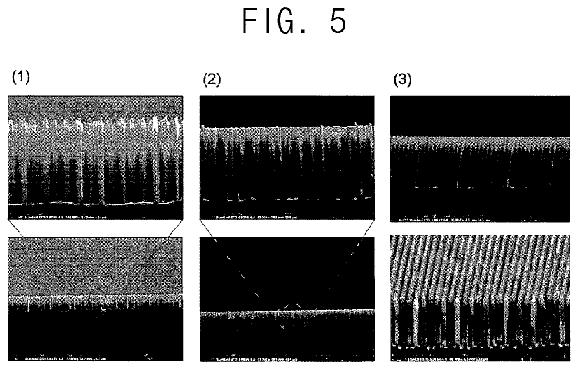

FIG. 5 are SEM images showing nanostructures formed on an upper surface of the substrate body using the method of FIG. 1.

As illustrated in FIG. 5, the nanostructures 11 may be formed on the substrate body 10 in the form of nanowire, nanowall and so on, according to the pattern of the metal layer 20. For example, the nanostructure 11 may be nanowires each having a diameter of 100 nm and a height of 2.5 μm (referring to FIG. 5 (1)), the nanostructure 11 may be nanowires each having a diameter of 200 nm and a height of 6 μm (referring to FIG. 5 (2)), the nanostructure 11 may be nanowires each having a diameter of 400 nm and a height of 12 μm (referring to FIG. 5 (3)), and the nanostructure 11 may be nanowalls each having a width of 100 nm and a height of 2 μm (referring to FIG. 5 (4)). Here, each of the nanostructures 11 was uniformly formed to have a high aspect ratio of 20:1 to 30:1. In addition, the metal layer 20 was used to uniformly form the nanostructures 11 without being damaged with minimal bending while being used as a catalyst for the etching solution.

Through the step S104, the metal layer 20 may be transferred to the substrate body 10 with a predetermined pattern having a uniform thickness. Thus, the metal layer 20 acts as the catalyst for the etching solution uniformly on the substrate body 10, so that the nanostructures may be formed to have uniform height as a whole. Thus, via the method for performing the nanotransfer, the nanostructures are uniformly and precisely formed along the metal layer transferred on the substrate.

Further, using the method for performing the nanotransfer according to the present example embodiment, the substrate 10 having the nanostructures 11 may be fabricated. The substrate 10 fabricated by the method may be used for a photodetector, a fuel cell and so on.

According to the present example embodiments, the metal pattern may be firmly transferred on the substrate without the chemical treatment such as the chemical surface treatment, the chemical adhesive, the chemical solvent and so on.

In addition, the metal pattern may be transferred on the substrate simply and at a low cost without defects.

In addition, the nanostructure may be easily formed according to the metal pattern transferred on the substrate.

In addition, the nanostructure may be formed on the substrate over a relatively larger area.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A method for performing nanotransfer on a substrate, the method comprising:
(a) forming a polymer mold having a mold protrusion, the mold protrusion being formed on a lower surface of the polymer mold and having a predetermined pattern;
(b) depositing a metal on the lower surface of the polymer mold, to form a metal layer on the mold protrusion;
(c) positioning the polymer mold on an upper surface of a substrate body at a predetermined temperature and pressurizing the substrate body by a predetermined time with a predetermined pressure, so that the metal layer is transferred on the upper surface of the substrate body according to a predetermined pattern; and
(d) detaching the polymer mold from the substrate body, so that the polymer mold is separated from the metal layer transferred on the upper surface of the substrate body.

2. The method of claim 1, wherein the predetermined temperature is between about 160° C. and about 200° C., the predetermined pressure is between about 3 bar and about 6 bar, and the predetermined time is between about 1 minutes and about 10 minutes.

3. The method of claim 1, wherein the metal layer has a thickness between about 20 nm and about 40 nm.

4. The method of claim 1, wherein the substrate body comprises at least one of silicon, germanium and gallium arsenide, and the metal comprises one of gold, silver and platinum.

5. The method of claim 1, wherein in the step (d), the polymer mold is cooled down for about 0.9 minutes to about 1.1 minutes with a temperature of about 23° C. to about 28° C., and then the polymer mold is separated from the substrate body.

6. The method of claim 1, further comprising:
coating an etching solution on the upper surface of the substrate body, so that an area in which the metal layer remains is removed and nanostructures are generated, after the step (d).

7. The method of claim 6, wherein the etching solution comprises acids having hydrofluoric acid or sulfuric acid, oxidizing agents having hydrogen peroxide or potassium permanganate, isopropyl alcohol and deionized water.

8. The method of claim 1, wherein in the step (c), the upper surface of the substrate body is not chemically treated.

9. A substrate comprising:
a substrate body having at least one of silicon, germanium and gallium arsenide; and
a metal layer transferred on an upper surface of the substrate body with a predetermined pattern,
wherein native oxide is generated between the substrate body and the metal layer, a eutectic bonding force acts between the metal layer and the native oxide, so that the substrate body and the metal layer are physically combined with each other.

10. The substrate of claim 9, wherein the metal layer has one of gold, silver and platinum.

11. The substrate of claim 9, wherein the metal layer has a thickness between about 20 nm and 40 nm.

12. The substrate of claim 9, wherein atoms on a lower surface of the metal layer are inserted between atoms on the upper surface of the substrate body, so that the metal layer is physically combined with the upper surface of the substrate body and the metal layer is transferred on the upper surface of the substrate body.

13. The substrate fabricated by the method of claim 1.
